(19) United States
(12) Patent Application Publication
(10) Pub. No.: US 2016/0260707 A1
(43) Pub. Date: Sep. 8, 2016

(54) SEMICONDUCTOR DEVICE

(71) Applicant: TOYOTA JIDOSHA KABUSHIKI KAISHA, Toyota-shi (JP)

(72) Inventor: Yoshifumi YASUDA, Nissin-shi (JP)

(73) Assignee: TOYOTA JIDOSHA KABUSHIKI KAISHA, Toyota-shi (JP)

(21) Appl. No.: 15/010,424

(22) Filed: Jan. 29, 2016

(30) Foreign Application Priority Data
Mar. 2, 2015 (JP) 2015-040710

(51) Int. Cl. H01L 27/06; H01L 29/739; H01L 49/02

(52) U.S. Cl. CPC H01L 27/0635; H01L 28/60; H01L 29/7395

(57) ABSTRACT

A semiconductor device disclosed herein includes a semiconductor substrate, a first main electrode in contact with a front surface of the semiconductor substrate, a second main electrode, a rear electrode in contact with a rear surface of the semiconductor substrate, a first capacitor electrode located on the front surface, a first insulating film located on the first capacitor electrode and a second capacitor electrode located on the first insulating film. The first insulated gate type switching element is provided between the first main electrode and the rear electrode. The second insulated gate type switching element is provided between the second main electrode and the rear electrode. One of the first main electrode and the second main electrode is electrically connected to the first capacitor electrode, and the other of the first main electrode and the second main electrode is electrically connected to the second capacitor electrode.

### CROSS-REFERENCE TO RELATED APPLICATION

This application claims priority to Japanese Patent Application No. 2015-040710 filed on Mar. 2, 2015, the entire contents of which are hereby incorporated by reference into the present application.

### TECHNICAL FIELD

A technique disclosed herein relates to a semiconductor device.

### DESCRIPTION OF RELATED ART

Japanese Patent Application Publication No. 2003-229572 A discloses a semiconductor device having insulated gate type switching elements. A main switching element and a sense switching element are provided on a semiconductor substrate of the semiconductor device. A size of the sense switching element is smaller than a size of the main switching element. A first main electrode (a first emitter) and a second main electrode (a second emitter) are provided on a front surface of the semiconductor substrate. A rear electrode (collector) is provided on a rear surface of the semiconductor substrate. The main switching element switches an electric current between the first main electrode and the rear electrode. The sense switching element switches an electric current between the second main electrode and the rear electrode. The first main electrode of the main switching element is directly connected to a reference potential (a shared emitter). The second main electrode of the sense switching element is connected to the reference potential via a sense resistor. Thus, a voltage according to the electric current flowing to the sense switching element is outputted to both ends of the sense resistor. In addition, a ratio of the electric current flowing in the sense switching element to the electric current flowing in the main switching element is substantially equal to a ratio of the size of the sense switching element to the size of the main switching element. By detecting the voltage of the sense resistor, the electric current flowing to the main switching element can be detected.

A surge may be applied to the second main electrode. When a high voltage is applied between the second main electrode and a gate of the sense switching element by the surge, a gate insulating film of the sense switching element can be deteriorated. To solve this problem, in the semiconductor device in JP 2003-229572 A, a zener diode is connected between the first main electrode and the second main electrode. The zener diode is provided on the semiconductor substrate. When the surge is applied to the second main electrode, breakdown occurs in the zener diode to flow a surge current from the second main electrode to the first main electrode. Thus, a potential of the second main electrode is prevented from being increased, thereby protecting the gate insulating film of the sense switching element.

### SUMMARY

When the semiconductor device in JP 2003-229572 A is turned on, the voltage is generated between both ends of the sense resistor, so that a potential of the second main electrode becomes higher than the reference potential. The first main electrode, which is directly connected to the reference potential, has a potential equal to the reference potential. Consequently, a potential difference is generated between the first main electrode and the second main electrode. The potential difference is applied to the zener diode. In addition, when the semiconductor device is on, the semiconductor substrate becomes hot. Consequently, the zener diode provided on the semiconductor substrate also becomes hot. When the potential difference is applied to the hot zener diode, a leak current flows to the zener diode. When the leak current flows to the zener diode, the ratio of the electric current flowing in the sense switching element to the electric current flowing in the main switching element is changed. Due to this, the electric current in the main switching element cannot be precisely calculated from the voltage in the sense resistor. That is, in the semiconductor device in JP 2003-229572 A, a detection accuracy of the electric current in the main switching element is low. Accordingly, herein, provided is a semiconductor device which can protect a sense switching element from a surge and can detect an electric current in a main switching element by using the sense switching element at high accuracy.

A semiconductor device disclosed herein comprises a semiconductor substrate, a first main electrode, a second main electrode, a rear electrode, a first capacitor electrode, a first insulating film and a second capacitor electrode. The first and second main electrodes are in contact with a front surface of the semiconductor substrate. The rear electrode is in contact with a rear surface of the semiconductor substrate. The first capacitor electrode is located on the front surface. The first insulating film is located on the first capacitor electrode. The second capacitor electrode is located on the first insulating film. The first main electrode and the second main electrode are in contact with the front surface in ranges different from each other. The first insulated gate type switching element is provided in a portion of the semiconductor substrate that is located between the first main electrode and the rear electrode. The second insulated gate type switching element is provided in a portion of the semiconductor substrate that is located between the second main electrode and the rear electrode. The area of the first insulated gate type switching element at the front surface is larger than an area of the second insulated gate type switching element at the front surface. One of the first main electrode and the second main electrode is electrically connected to the first capacitor electrode, and the other of the first main electrode and the second main electrode is electrically connected to the second capacitor electrode.

In the semiconductor device, the second insulated gate type switching element having a small area can be used as a sense switching element. The first capacitor electrode, the first insulating film, and the second capacitor electrode configure a capacitor. The capacitor is interposed between the first main electrode and the second main electrode. The capacitor has a low impedance with respect to a voltage having a high change rate. Thus, when a surge is applied to the second main electrode, a surge current flows from the second main electrode toward the first main electrode via the capacitor. With this, the second insulated gate type switching element is protected from the surge. In addition, the capacitor has a high impedance with respect to a voltage having a low change rate. Thus, even when a voltage generated due to a sense resistor (a voltage having a low change rate (a substantially direct current voltage)) is applied between the first main electrode and the second main electrode during operation of the semiconductor device, the electric current does not flow to the capacitor. Further, a leak current hardly flows through the capacitor even at high temperature. Thus, in the semiconductor device, a ratio of an electric current flowing in the first insulated gate type switching element to an electric current flowing in the second insulated gate type switching element is hard to be changed. The electric current flowing to the semiconductor device can thus be precisely detected.

### BRIEF DESCRIPTION OF THE DRAWINGS

FIG. 1 is a circuit diagram of a semiconductor device;

FIG. 2 is a plan view of the semiconductor device;

FIG. 3 is an enlarged plan view of the semiconductor device in a range near a sense emitter electrode;

FIG. 4 is a longitudinal cross-sectional view of the semiconductor device taken along line A-A in FIG. 3;

FIG. 5 is a longitudinal cross-sectional view of the semiconductor device taken along line B-B in FIG. 3;

FIG. 6 is a longitudinal cross-sectional view of the semiconductor device taken along line C-C in FIG. 3;

FIG. 7 is a longitudinal cross-sectional view of a semiconductor device of a modification corresponding to FIG. 4; and

FIG. 8 is an enlarged plan view of a semiconductor device of Embodiment 2 in a range near the sense emitter electrode.

### DETAILED DESCRIPTION

### Embodiment 1

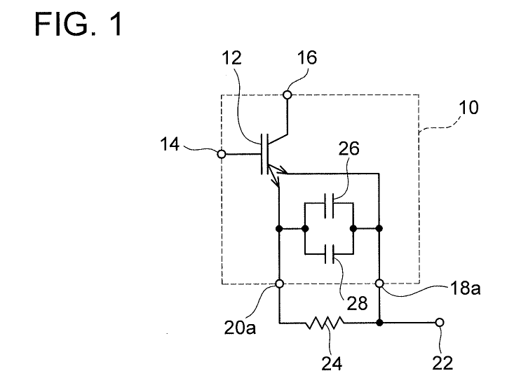

FIG. 1 illustrates a circuit diagram of a semiconductor device 10 according to an embodiment. The semiconductor device 10 has an IGBT 12, a capacitor 26, and a capacitor 28. The IGBT 12 has a gate pad 14, a collector electrode 16, a main emitter electrode 18a, and a sense emitter electrode 20a. The capacitor 26 is connected between the main emitter electrode 18a and the sense emitter electrode 20a. The capacitor 28 is connected between the main emitter electrode 18a and the sense emitter electrode 20a. That is, the capacitors 26 and 28 are connected in parallel. The main emitter electrode 18a is connected to an external electrode 22. The sense emitter electrode 20a is connected to the external electrode 22 via a sense resistor 24.

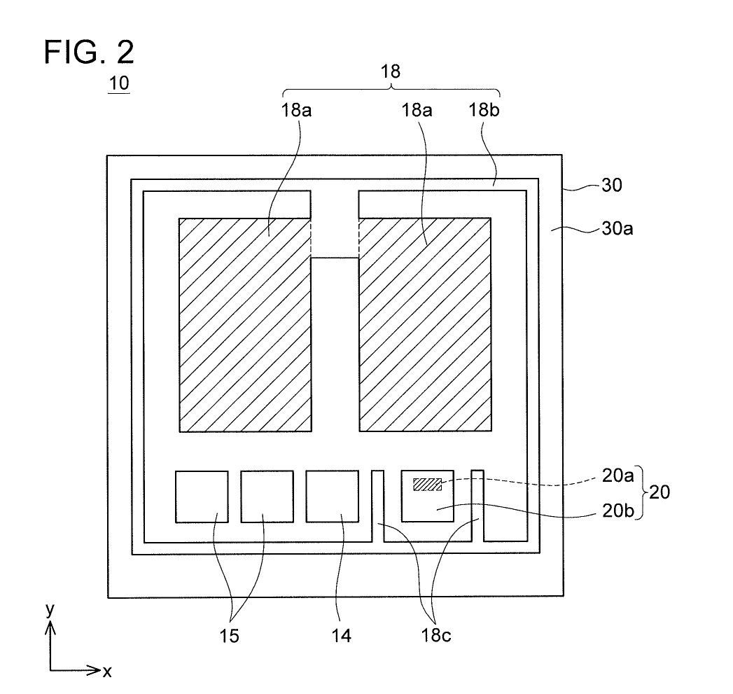

As illustrated in FIG. 2, the semiconductor device 10 has a semiconductor substrate 30 made of silicon. Metal layers 18, 20, 14, and 15 mainly configured of aluminum are provided on a front surface 30a of the semiconductor substrate 30. For easy viewing of the drawings for reference herein including FIG. 2, some wirings such as gate wiring are not illustrated. In addition, in the following, a left-right direction in FIG. 2 (a direction parallel with one side of the semiconductor substrate 30 when the front surface 30a is seen in a plan view) is referred to as an x direction, and an up-down direction in FIG. 2 (a direction orthogonal to the x direction when the front surface 30a is seen in a plan view) is referred to as a y direction.

Each metal layer 18a of the metal layer 18 in hatched range in FIG. 2 is in contact with the front surface of the semiconductor substrate 30. A main IGBT is provided below the metal layer 18a in the hatched range. The metal layer 18a in the hatched range configures the main emitter electrode 18a illustrated in FIG. 1. A portion of the metal layer 18 out of the hatched range is a wiring layer where a lower surface of the metal layer 18 is not in contact with the semiconductor substrate 30. That is, an insulating film is located between the wiring layer and the semiconductor substrate 30. The wiring layer has an annular portion 18b extending annularly along an outer peripheral edge of the semiconductor substrate 30. The annular portion 18b is connected to the main emitter electrode 18a. The wiring layer also has two extending portions 18c extending from the annular portion 18b along both sides of the metal layer 20.

The metal layer 20 is located adjacent to the main emitter electrode 18a in the y direction. A metal layer 20a of the metal layer 20 in a hatched range in FIG. 2 is in contact with the front surface of the semiconductor substrate 30. A sense IGBT is provided below the metal layer 20a in the hatched range. The metal layer 20a in the hatched range configures the sense emitter electrode 20a illustrated in FIG. 1. A portion of the metal layer 20 out of the hatched range is a wiring layer 20b where a lower surface of the metal layer 20 is not in contact with the semiconductor substrate 30. That is, an insulating film is located between the wiring layer 20b and the semiconductor substrate 30. The wiring layer 20b is located around the sense emitter electrode 20a.

The metal layer 14 is located adjacent to the metal layer 20 in the x direction. The metal layer 14 is the gate pad 14 in FIG. 1, and is connected to gate electrodes of the main IGBT and the sense IGBT by the gate wirings, not illustrated. Two pads 15 for temperature detection are provided on the front surface 30a of the semiconductor substrate 30.

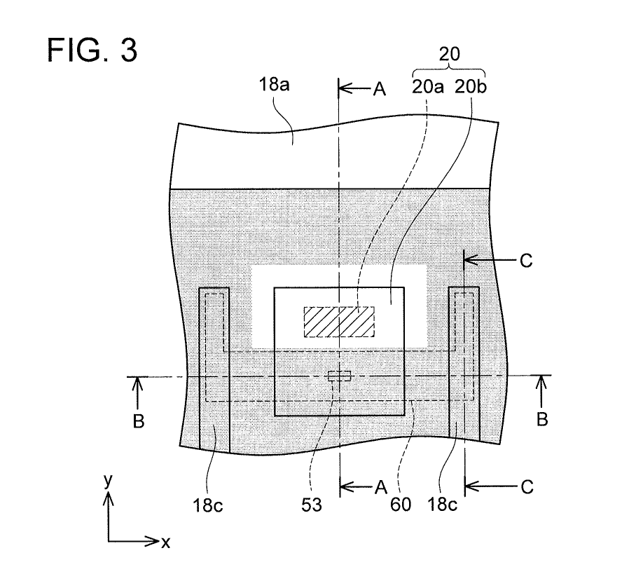

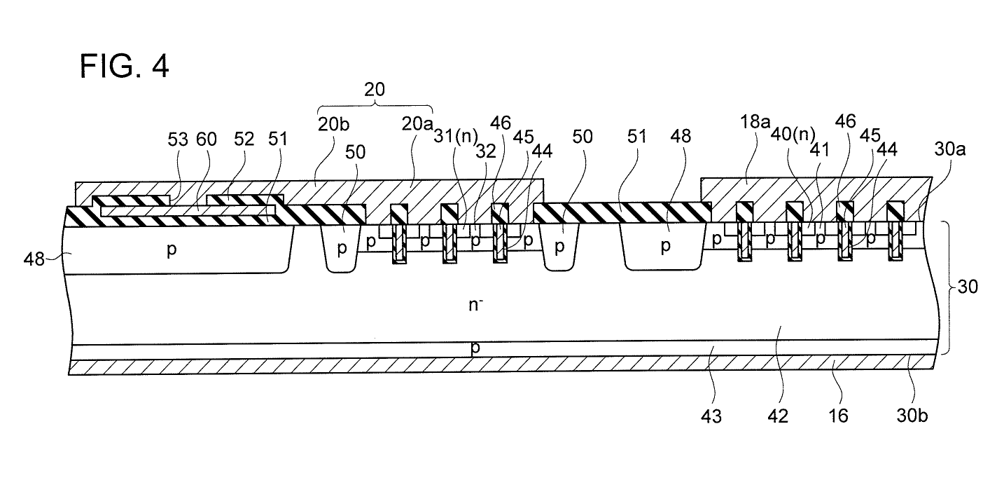

FIG. 3 illustrates an enlarged view around the sense emitter electrode 20a in FIG. 1. FIG. 4 illustrates a longitudinal cross-sectional view taken along line A-A in FIG. 3. For description, thicknesses of interlayer insulating films and wirings on the semiconductor substrate 30 in FIG. 4 and FIGS. 5 and 6 to be described below are extremely larger than the actual thicknesses. As illustrated in FIG. 4, the collector electrode 16 is provided in an entire rear surface 30b) of the semiconductor substrate 30.

As illustrated in FIG. 4, a plurality of emitter regions 40, body region 41, a drift region 42, and a collector region 43 are provided in the semiconductor substrate 30 below the main emitter electrode 18a. Each emitter region 40 is an n-type region. The emitter region 40 is provided in a range exposed on the front surface 30a of the semiconductor substrate 30. The emitter region 40 is in ohmic contact with the main emitter electrode 18a. The body region 41 is a p-type region. The body region 41 is exposed on the front surface 30a of the semiconductor substrate 30 in a position adjacent to the emitter region 40. The body region 41 is also provided below the emitter region 40. A p-type impurity density of the body region 41 near the front surface 30a is higher than a p-type impurity density of the body region 41 below the emitter region 40. The body region 41 is in ohmic contact with the main emitter electrode 18a. The drift region 42 is an n-type region having a low n-type impurity density. The drift region 42 is provided below the body region 41. The collector region 43 is a p-type region. The collector region 43 is provided below the drift region 42. The collector region 43 is exposed on the rear surface 30b of the semiconductor substrate 30. The collector region 43 is in ohmic contact with the collector electrode 16 in the substantially entire rear surface 30b. A plurality of trenches is provided in the front surface 30a of the semiconductor substrate 30 below the main emitter electrode 18a. Each trench penetrates through the emitter region 40 and the body region 41, and reaches the drift region 42. A gate insulating film 44 and a gate electrode 45 are provided in each trench. The gate insulating film 44 covers an inner face of the trench. The gate electrode 45 is insulated from the semiconductor substrate 30 by the gate insulating film 44. The gate electrode 45 faces the emitter region 40, the body region 41, and the drift region 42 via the gate insulating film 44. An upper surface of the gate electrode 45 is covered by an interlayer insulating film 46. The gate electrode 45 is insulated from the main emitter electrode 18a by the interlayer insulating film 46. The gate electrode 45 is connected to the gate pad 14 in FIG. 2 by the gate wiring, not illustrated. The main emitter electrode 18a, the emitter region 40, the body region 41, the drift region 42, the collector region 43, the collector electrode 16, the gate insulating film 44, and the gate electrode 45 configure the main IGBT. The main IGBT is provided in the semiconductor substrate 30 between the main emitter electrode 18a and the collector electrode 16. The main IGBT switches an electric current flowing between the main emitter electrode 18a and the collector electrode 16. The main IGBT is provided in the entire range overlapping with the main emitter electrode 18a illustrated in FIG. 2.

As illustrated in FIG. 4, a plurality of emitter regions 31, body region 32, the drift region 42, and the collector region 43 are provided in the semiconductor substrate 30 below the sense emitter electrode 20a. Each emitter region 31 is an n-type region. The emitter region 31 is provided in a range exposed on the front surface 30a of the semiconductor substrate 30. The emitter region 31 is in ohmic contact with the sense emitter electrode 20a. An n-type impurity density of the emitter region 31 is higher than an n-type impurity density of the drift region 42. Each body region 32 is a p-type region. The body region 32 is exposed in the front surface 30a of the semiconductor substrate 30 in a position adjacent to the emitter region 31. The body region 32 is also provided below the emitter region 31. A p-type impurity density of the body region 32 near the front surface 30a is higher than a p-type impurity density of the body region 32 below the emitter region 31. The body region 32 is in ohmic contact with the sense emitter electrode 20a. The drift region 42 and the collector region 43 are provided below the body region 32. The drift region 42 below the body region 32 is connected to the drift region 42 below the body region 41. The body region 32 is separated from the body region 41 by the drift region 42. The collector region 43 below the body region 32 is connected to the collector region 43 below the body region 41. The collector region 43 is also in ohmic contact with the collector electrode 16 in a position below the body region 32. A plurality of trenches is provided in the front surface 30a of the semiconductor substrate 30 below the sense emitter electrode 20a. Each trench penetrates through the emitter region 31 and the body region 32, and reaches the drift region 42. The gate insulating film 44 and the gate electrode 45 are provided in the trench. The gate insulating film 44 covers an inner face of the trench. The gate electrode 45 is insulated from the semiconductor substrate 30 by the gate insulating film 44. The gate electrode 45 faces the emitter region 31, the body region 32, and the drift region 42 via the gate insulating film 44. An upper surface of the gate electrode 45 is covered by the interlayer insulating film 46. The gate electrode 45 is insulated from the sense emitter electrode 20a by the interlayer insulating film 46. The gate electrode 45 below the sense emitter electrode 20a is connected to the gate pad 14 in FIG. 2 by the gate wiring, not illustrated. The sense emitter electrode 20a, the emitter region 31, the body region 32, the drift region 42, the collector region 43, the collector electrode 16, the gate insulating film 44, the gate electrode 45, and the like configure the sense IGBT. The sense IGBT is provided in the semiconductor substrate 30 between the sense emitter electrode 20a and the collector electrode 16. The sense IGBT switches an electric current flowing between the sense emitter electrode 20a and the collector electrode 16. The sense IGBT is provided in the entire range overlapping with the sense emitter electrode 20a illustrated in FIG. 2. As is apparent from FIG. 2, in the front surface 30a of the semiconductor substrate 30, an area of the sense IGBT (that is, an area of the sense emitter electrode 20a) is much smaller than an area of the main IGBT (that is, an area of the main emitter electrode 18a). Thus, the electric current flowing to the sense IGBT is much smaller than the electric current flowing to the main IGBT.

As illustrated in FIG. 4, a deep region 48 extending from the front surface 30a of the semiconductor substrate 30 to a position deeper than a lower end of the body region 41 is provided at an end of the body region 41 of the main IGBT. A p-type impurity density of the deep region 48 is higher than the p-type impurity density of the body region 41 below the emitter region 40. The deep region 48 is connected to the body region 41 of the main IGBT in the cross section illustrated in FIG. 4. The deep region 48 is connected to the main emitter electrode 18a via the body region 41. An upper surface of the deep region 48 is covered by an interlayer insulating film 51. The gray range in FIG. 3 is a range in which the deep region 48 is provided. As illustrated in FIG. 3, the deep region 48 is also provided below the extending portions 18c.

As illustrated in FIG. 4, a deep region 50 extending from the front surface 30a of the semiconductor substrate 30 to a position deeper than a lower end of the body region 32 is provided at an end of the body region 32 of the sense IGBT. The deep region 50 is connected to the body region 32 of the sense IGBT. The deep region 50 is connected to the sense emitter electrode 20a via the body region 32. An upper surface of the deep region 50 is covered by the interlayer insulating film 51. The deep region 50 is provided away from the deep region 48. The n-type drift region 42 is provided between the deep regions 50 and 48, and separates the deep region 50 from the deep region 48. The deep region 50 is provided only around the sense IGBT. The deep regions 48 and 50 prevent electric field concentration in a boundary between the main IGBT and the sense IGBT.

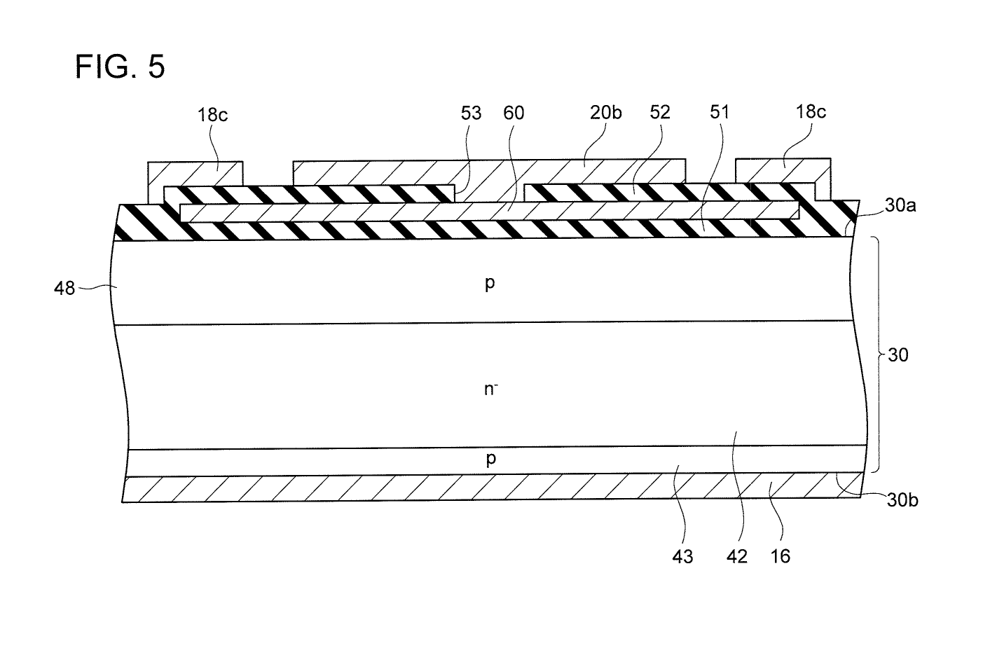

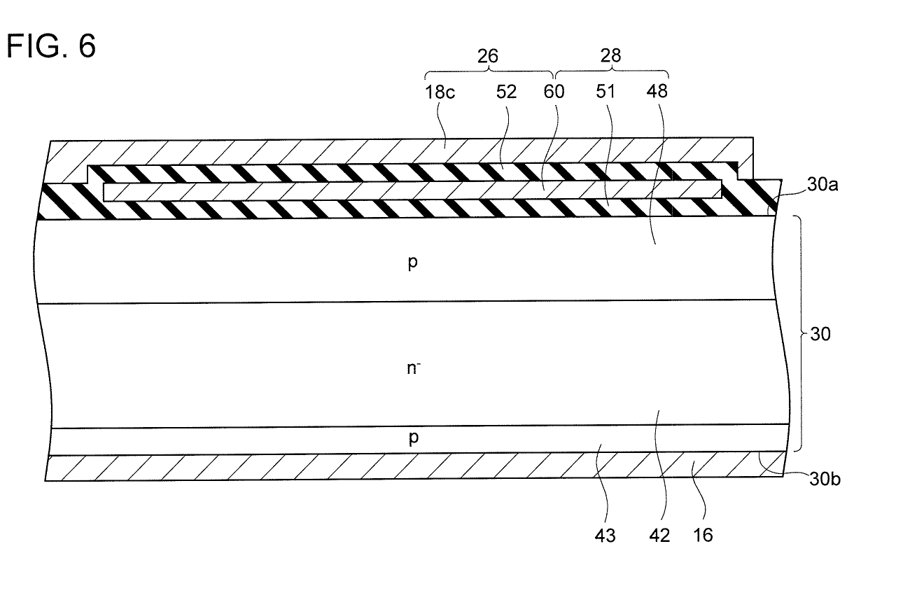

As illustrated in FIGS. 3 and 4, the wiring layer 20b extends from the sense emitter electrode 20a toward an outer periphery of the semiconductor substrate 30. The wiring layer 20b is located on the interlayer insulating film 51. Thus, the wiring layer 20b is not in direct contact with the semiconductor substrate 30. A wiring layer 60 configured of polysilicon is provided on a portion of the interlayer insulating film 51. An interlayer insulating film 52 is provided on the wiring layer 60. The wiring layer 20b covers the interlayer insulating film 52. A contact hole 53 is provided in the interlayer insulating film 52. The wiring layer 60 is connected to the wiring layer 20b through the contact hole 53. As illustrated in FIGS. 3 and 5, the wiring layer 60 elongatedly extends from a position of the contact hole 53 along the x direction. The wiring layer 60 extends to below the extending portions 18c. As illustrated in FIGS. 3 and 6, the wiring layer 60 is bent below the extending portions 18c, and elongatedly extends along the y direction, along the extending portions 18c. As illustrated in FIGS. 5 and 6, the interlayer insulating film 52 is provided between the wiring layer 60 and the extending portions 18c, and insulates the wiring layer 60 from the extending portions 18c. More specifically, the entire metal layer 18 including the extending portions 18c is insulated from the wiring layer 60 and the metal layer 20 connected to the wiring layer 60. The wiring layer 60 faces the extending portions 18c via the interlayer insulating film 52. That is, the wiring layer 60, the interlayer insulating film 52, and the extending portions 18c configure a capacitor. As described above, the extending portions 18c is connected to the main emitter electrode 18a. As described above, the wiring layer 60 is connected to the sense emitter electrode 20a. Thus, the capacitor configured by the wiring layer 60, the interlayer insulating film 52, and the extending portions 18c serves as the capacitor 26 connected between the main emitter electrode 18a and the sense emitter electrode 20a, as illustrated in FIG. 1.

As illustrated in FIGS. 3 and 6, the deep region 48 is provided below the entire wiring layer 60. The interlayer insulating film 51 is provided between the wiring layer 60 and the deep region 48, and insulates the wiring layer 60 from the deep region 48. More specifically, the deep region 48 is insulated from the wiring layer 60 and the metal layer 20 connected to the wiring layer 60. The wiring layer 60 faces the deep region 48 via the interlayer insulating film 51. The wiring layer 60, the interlayer insulating film 51, and the deep region 48 configure a capacitor. That is, the deep region 48 functions as one of electrode plates of the capacitor. As described above, the deep region 48 is connected to the main emitter electrode 18a. As described above, the wiring layer 60 is connected to the sense emitter electrode 20a. Thus, the capacitor configured by the wiring layer 60, the interlayer insulating film 51, and the deep region 48 serves as the capacitor 28 connected between the main emitter electrode 18a and the sense emitter electrode 20a, as illustrated in FIG. 1.

An operation of the, semiconductor device 10 will be described. When the IGBT 12 in FIG. 1 (that is, the main IGBT and the sense IGBT) is turned on, an electric current flows from the collector electrode 16 toward the external electrode 22. Most of the electric current flows via the main IGBT (that is, the main emitter electrode 18a). Part of the electric current flows via the sense IGBT (that is, the sense emitter electrode 20a). The electric current flowing in the sense IGBT can be measured by a potential difference between both ends of the sense resistor 24. Further, a ratio of the electric current flowing in the main IGBT to the electric current flowing in the sense IGBT is substantially equal to a ratio of an area of the main IGBT to an area of the sense IGBT. Thus, by detecting the electric current in the sense IGBT, the electric current in the main IGBT can be detected.

Since the potential difference is generated between both ends of the sense resistor 24, a potential difference is generated between the sense emitter electrode 20a and the main emitter electrode 18a. The potential difference is applied to the capacitors 26 and 28. In a state where the electric current flowing to each IGBT is stable, the potential difference generated between both ends of the sense resistor 24 is substantially constant. Since the substantially constant potential difference is applied to the capacitors 26 and 28, the electric currents do not flow to the capacitors 26 and 28. When the IGBT 12 is turned on, the semiconductor substrate 30 becomes hot. Consequently, the capacitors 26 and 28 provided on the front surface of the semiconductor substrate 30 also become hot. However, since both electrode plates of the capacitor 26 (that is, the extending portions 18c and the wiring layer 60) are insulated by the interlayer insulating film 52, a leak current is hardly caused in the capacitor 26 even when the capacitor 26 becomes hot. In addition, since both electrode plates of the capacitor 28 (that is, the wiring layer 60 and the deep region 48) are insulated by the interlayer insulating film 51, a leak current is hardly caused in the capacitor 28 even when the capacitor 28 becomes hot. Since the leak current is hard to be caused, the ratio of the electric current flowing to the sense IGBT to the electric current flowing to the main IGBT is hard to be changed. In the semiconductor device 10, the electric current flowing in the main IGBT can be precisely detected from a voltage of the sense resistor 24.

A surge may be applied to the sense emitter electrode 20a of the semiconductor device 10. Since a capacity between the emitter and the gate of the sense IGBT is small, when a high voltage is applied between the emitter and the gate by the surge, the gate insulating film 44 of the sense IGBT can be deteriorated. However, in this Embodiment, the capacitors 26 and 28 are interposed between the sense emitter electrode 20a and the main emitter electrode 18a. Since the capacitors 26 and 28 have lower impedances with respect to a voltage having a high change rate, such as the surge, when the surge is applied to the sense emitter electrode 20a, a surge current flows from the sense emitter electrode 20a to the main emitter electrode 18a via the capacitors 26 and 28. With this, a rise in a potential of the sense emitter electrode 20a is suppressed, and a high voltage is prevented from being applied between the emitter and the gate of the sense IGBT. The gate insulating film of the sense IGBT is thus protected from the surge. In particular, in this Embodiment, the two capacitors 26 and 28 are connected in parallel between the sense emitter electrode 20a and the main emitter electrode 18a. Due to this, an electrostatic capacity between the sense emitter electrode 20a and the main emitter electrode 18a is increased. By increasing the electrostatic capacity in this manner, the potential of the sense emitter electrode 20a is harder to be raised when the surge is applied. The gate insulating film of the sense IGBT is thus protected more preferably.

As described above, in the semiconductor device 10 of Embodiment 1, the electric current flowing in the main IGBT can be precisely detected, and the sense IGBT can be suitably protected from the surge.

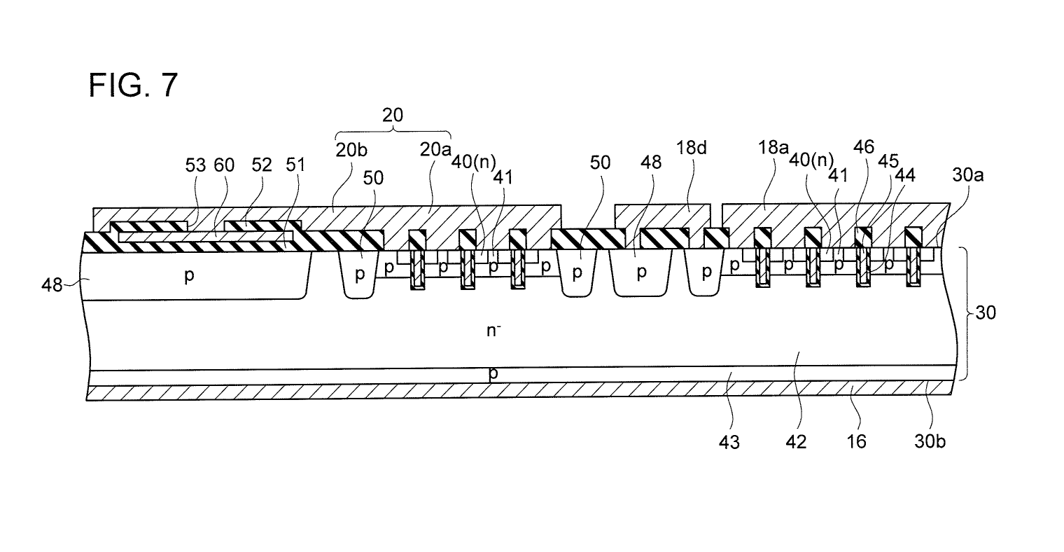

In the semiconductor device 10 of Embodiment 1, the deep region 48 is directly connected to the body region 41. However, as illustrated in FIG. 7, the deep region 48 may be connected to the body region 41 via a conductor, such as a wiring layer 18d. That is, when a direct current can flow from the deep region 48 to the main emitter electrode 18a, the deep region 48 may be connected in any manner.

A relation between each component of Embodiment 1 and each component of the claims will be described below. The main emitter electrode 18a of Embodiment 1 is an example of the claimed first main electrode. The sense emitter electrode 20a of Embodiment 1 is an example of the claimed second main electrode. The collector electrode 16 of Embodiment 1 is an example of the claimed rear electrode. The wiring layer 60 of Embodiment 1 is an example of the claimed first capacitor electrode of the claims. The interlayer insulating film 52 of Embodiment 1 is an example of the claimed first insulating film. The extending portion 18c of Embodiment 1 is an example of the claimed second capacitor electrode. The interlayer insulating film 51 of Embodiment 1 is an example of the claimed second insulating film. The deep region 48 of Embodiment 1 is an example of the claimed capacitor region. The main IGBT of Embodiment 1 is an example of the claimed first insulated gate type switching element. The sense IGBT of Embodiment 1 is an example of the claimed second insulated gate type switching element of the claims.

### Embodiment 2

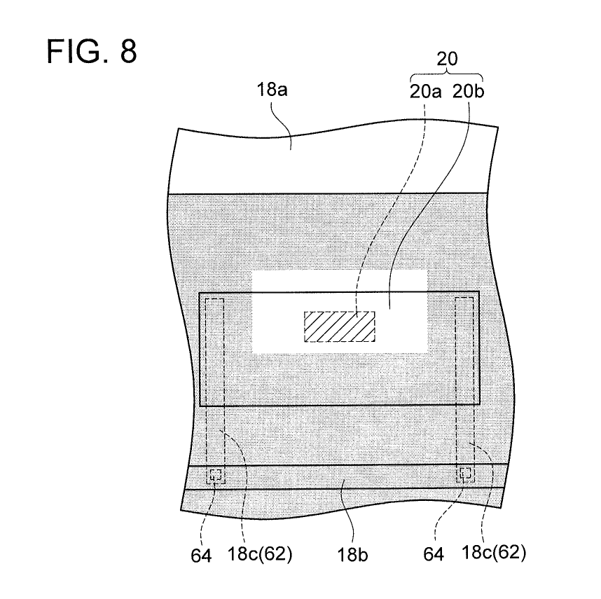

A semiconductor device of Embodiment 2 has a capacitor structure different from that of the semiconductor device 10 of Embodiment 1. Other than that, the semiconductor device of Embodiment 2 is identical to the semiconductor device 10 of Embodiment 1. In Embodiment 2, as illustrated in FIG. 8, each extending portion 18c is configured of a polysilicon layer 62. Like the wiring layer 60 in FIGS. 5 and 6, the polysilicon layer 62 is insulated from the semiconductor substrate 30 by the interlayer insulating film 51. An upper surface of the polysilicon layer 62 is covered by the interlayer insulating film 52. An end of the polysilicon layer 62 is provided below the annular portion 18b of the metal layer 18. A contact hole 64 is provided in the interlayer insulating film 51 below the annular portion 18b, and the polysilicon layer 62 is connected to the annular portion 18b through the contact hole 64. Thus, the polysilicon layer 62 is connected to the main emitter electrode 18a via the annular portion 18b. The polysilicon layer 62 extends below the wiring layer 20b. The wiring layer 20b is insulated from the polysilicon layer 62 by the interlayer insulating film 52.

In the structure of Embodiment 2, the wiring layer 20b, the polysilicon layer 62 (the extending portions 18c), and the interlayer insulating film 52 located between these configure a capacitor. The wiring layer 20b is connected to the sense emitter electrode 20a, and the polysilicon layer 62 is connected to the main emitter electrode 18a, so that the capacitor configures the capacitor 26 in FIG. 1. In Embodiment 2, the capacitor 28 in FIG. 1 is not provided because both the polysilicon layer 62 and the deep region 48 therebelow are connected to the main emitter electrode 18a.

In the structure of Embodiment 2, the sense IGBT can be protected from a surge by the capacitor 26. Since a leak current is hard to flow to the capacitor 26, an electric current flowing in the main IGBT can be precisely detected.

A relation between each component of Embodiment 2 and each component of the claims will be described below. The main emitter electrode 18a of Embodiment 2 is an example of the claimed first main electrode. The sense emitter electrode 20a of Embodiment 2 is an example of the claimed second main electrode. The collector electrode 16 of Embodiment 2 is an example of the claimed rear electrode. The polysilicon layer 62 of Embodiment 2 is an example of the claimed first capacitor electrode. The interlayer insulating film 52 of Embodiment 2 is an example of the claimed first insulating film. The wiring layer 20b of Embodiment 2 is an example of the claimed second capacitor electrode of the claims.

In Embodiment 2, the deep region 48 connected to the main emitter electrode 18a is provided below the polysilicon layer 62. However, the deep region 50 connected to the sense emitter electrode 20a may be provided below the polysilicon layer 62. Due to this structure, the polysilicon layer 62, the deep region 50, and the interlayer insulating film 51 between these can provide the capacitor 28 in FIG. 1.

In Embodiments 1 and 2, the IGBT is provided on the semiconductor substrate 30, but, in place of the IGBT, another insulated gate type switching element (e.g., MOSFET) may be provided.

In the structure disclosed in JP 2003-229572 A in which the switching element is protected from the surge by the zener diode, the zener diode is configured by the polysilicon layer located on the semiconductor substrate. The zener diode is configured by implanting p-type and n-type impurities into the polysilicon layer. Typically, to reduce the number of manufacturing steps, the impurity implantation step for providing the zener diode is performed with the impurity implantation step for providing the switching element in the semiconductor device. Thus, according to the characteristic necessary for the switching element, the characteristics of the zener diode are changed, so that the protection ability of the zener diode cannot be controlled independently. In the methods of Embodiments 1 and 2, such a problem does not arise because the protection from the surge is performed by the capacitor.

The technical elements disclosed herein will be explained. In one aspect of the present disclosure, a second insulating film may be interposed between the first capacitor electrode and the front surface of a semiconductor substrate. A capacitor region electrically connected to the main electrode electrically connected to the second capacitor electrode may be provided in a part of the semiconductor substrate facing the first capacitor electrode via the second insulating film.

In this structure, the first capacitor electrode, the second insulating film, and the capacitor region configure a second capacitor. The second capacitor is connected between the first main electrode and the second main electrode. That is, in this structure, two capacitors are connected in parallel between the first main electrode and the second main electrode. Due to this, a capacity between the first main electrode and the second main electrode becomes larger. The insulated gate type switching element can thus be protected from a surge more preferably.

The embodiments have been described in detail in the above. However, these are only examples and are not intended to limit the claims. The claims are intended to encompass various modifications and changes of the concrete examples described above. The technical aspects explained herein exert technical utility independently or in various combinations, and the combinations are not limited to those described in the claims as filed. Moreover, the aspects exemplified in the present disclose achieve a plurality of objects at the same time, and have technical utility by achieving one or more of such objects.

1. A semiconductor device, comprising:
a semiconductor substrate;
a first main electrode and a second main electrode which are in contact with a front surface of the semiconductor substrate;
a rear electrode being in contact with a rear surface of the semiconductor substrate;
a first capacitor electrode located on the front surface;
a first insulating film located on the first capacitor electrode;
a second capacitor electrode located on the first insulating film,
wherein
the first main electrode and the second main electrode are in contact with the front surface in ranges different from each other,
a first insulated gate type switching element is provided in a portion of the semiconductor substrate located between the first main electrode and the rear electrode,
a second insulated gate type switching element is provided in a portion of the semiconductor substrate located between the second main electrode and the rear electrode,
an area of the first insulated gate type switching element at the front surface is larger than an area of the second insulated gate type switching element at the front surface,
one of the first main electrode and the second main electrode is electrically connected to the first capacitor electrode, and
the other of the first main electrode and the second main electrode is electrically connected to the second capacitor electrode.

2. The semiconductor device of claim 1, wherein
a second insulating film is interposed between the first capacitor electrode and the front surface, and
a capacitor region being electrically connected to the other is provided in a part of the semiconductor substrate facing the first capacitor electrode via the second insulating film.
